(19) United States
(12) Patent Application Publication
(10) Pub. No.: US 2012/0017987 A1
(43) Pub. Date: Jan. 26, 2012

(54) SOLAR CELL APPARATUS

(75) Inventors: ZHONG-LIANG LU, Shenzhen City (CN); SHIH-HSUN WUNG, Tu-Cheng (TW)

(73) Assignees: FOXCONN TECHNOLOGY CO., LTD., Tu-Cheng (TW); FU ZHUN PRECISION INDUSTRY (SHEN ZHEN) CO., LTD., Shenzhen City (CN)

(21) Appl. No.: 12/848,230

(22) Filed: Aug. 2, 2010

(30) Foreign Application Priority Data
Jul. 23, 2010 (CN) 201010235458.7

(51) Int. Cl. H01L 31/024

(52) U.S. Cl. 136/259

(57) ABSTRACT

A solar cell apparatus includes a heat sink and a solar cell panel. The heat sink includes a base, a fin set, and a heat pipe thermally connecting the fin set and the base. The solar cell panel is attached on a top face of the heat sink. A fixing bracket supports the heat sink and holds a lens above the heat sink for focusing sunlight on the solar cell panel.

### BACKGROUND

1. Technical Field

The disclosure relates to solar cell apparatuses and, particularly, to a solar cell apparatus having a good heat dissipation performance.

2. Description of Related Art

The solar cell apparatus is well known as a cost-effective power supply device, which converts light power to electrical power. Nowadays, the solar cell apparatuses are widely used in various areas. Generally, the solar cell apparatus comprises at least a solar cell panel and a light-reflecting board to focus solar towards the solar cell panel.

However, the solar cell panel usually requires a large quantity of sunlight focused thereon for producing adequate electricity power, which results in a rapid rise in operating temperature of the solar cell panel, and may damage the solar cell panel.

What is needed, therefore, is a solar cell apparatus which can overcome the described limitations.

### BRIEF DESCRIPTION OF THE DRAWINGS

Many aspects of the present apparatus can be better understood with reference to the following drawings. The components in the drawings are not necessarily drawn to scale, the emphasis instead being placed upon clearly illustrating the principles of the present apparatus. Moreover, in the drawings, like reference numerals designate corresponding parts throughout the several views.

FIG. 1 is an isometric, assembled view of a solar cell apparatus in accordance with an embodiment of the disclosure.

FIG. 2 is an exploded view of the solar cell apparatus of FIG. 1.

FIG. 3 is a cross sectional view of the solar cell apparatus of FIG. 1, taken along line III-III thereof.

### DETAILED DESCRIPTION

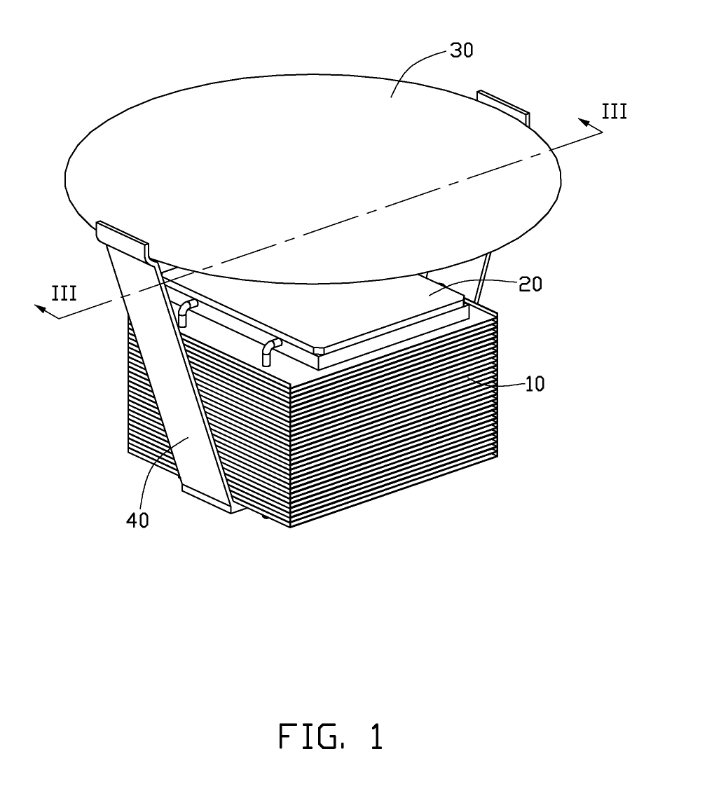

Referring to FIG. 1, a solar cell apparatus in accordance with an embodiment of the disclosure has a good heat dissipation performance. The solar cell apparatus comprises a heat sink 10, a solar cell panel 20 mounted on the heat sink 10, and a lens 30 located above the solar cell panel 20, and a fixing bracket 40 fixing the lens 30 and the heat sink 10 together.

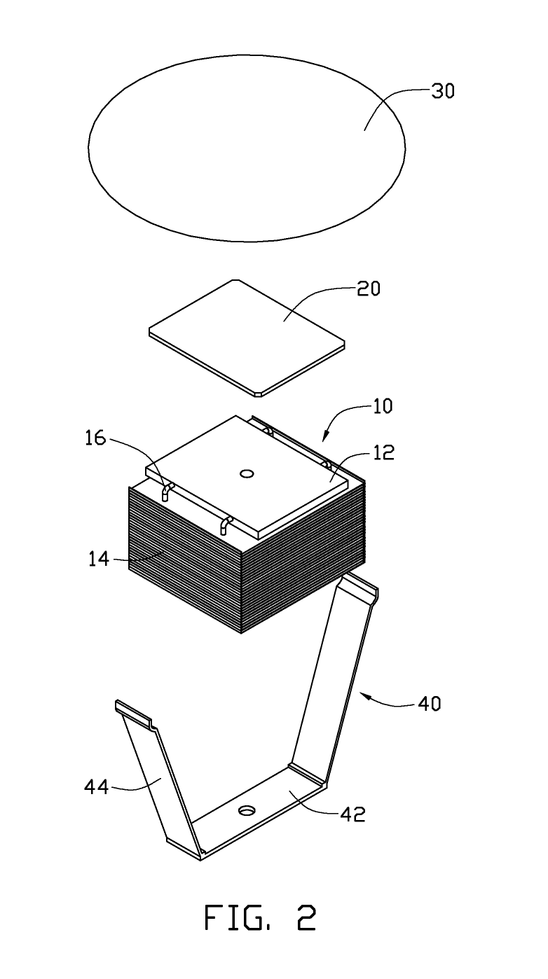

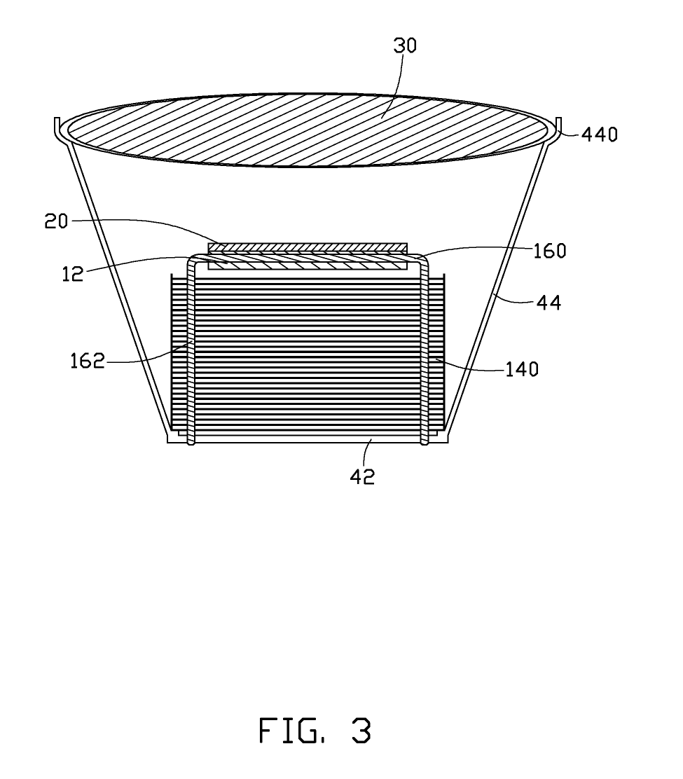

Referring to FIGS. 2-3 also, the heat sink 10 comprises a base 12, a fin set 14, and at least a heat pipe 16 thermally connecting the fin set 14 with the base 12. In the embodiment of the present disclosure, two heat pipes 16 are used for increasing heat dissipation capability of the heat sink 10. The base 12 is a rectangular plate and integrally made of a metal with good heat conductivity such as aluminum, copper or an alloy thereof. The base 12 has a top face contacting with the solar cell panel 20.

The fin set 14 is separated from the base 12 and comprises a plurality of fins 140 spaced from each other. The fins 140 are substantially rectangular metallic sheets and parallel to each other and the base 12. A plurality of air passages (not labeled) are defined between every two neighboring fins 140 for airflow flowing therethrough to bring heat into ambient environment.

Each heat pipe 16 is bent into a U-shape and comprises an evaporation section 160 and two condensation sections 162 extending downwardly from two opposite ends of the evaporation section 160. The evaporation section 160 of the heat pipe 16 is embedded in the base 12. The evaporation section 160 of the heat pipe 16 is located adjacent to the solar cell panel 20. The two condensation sections 162 of the heat pipe 16 are perpendicularly extended through the fins 140 and securely received in two receiving holes (not labeled) defined in the fin set 14, respectively. The condensation sections 162 are located adjacent to two lateral sides of the fin set 14.

The lens 30 is integrally made of transparent materials selected from glass, resin, PC (polycarbonate) and PMMA (polymethyl methacrylate). The lens 30 has a light-emergent face (not labeled) facing to the solar cell panel 20 and a light-incident face (not labeled) opposite to the light-emergent face. The light-emergent face and the light-incident face are both curved, for focusing sunlight passing through the lens 30 on the solar cell panel 20. A thickness of the lens 30 decreases gradually from a central portion to a periphery of the lens 30. In the embodiment of this disclosure, a cross section of the lens 30 has a shape substantially like an ellipse, and the lens 30 is a convex lens.

The fixing bracket 40 is integrally formed by stamping and bending a metal sheet. The fixing bracket 40 is U-shaped and comprises a horizontal section 42 and a pair of fixing arms 44 respectively extending upwardly from two opposite ends of the horizontal section 42 for suspending the lens 30 above the solar cell panel 20. Two upper ends of the two fixing arms 44 each are bended to form an engaging portion 440, for respectively abutting against and supporting two opposite lateral sides of the lens 30. The heat sink 10 and the solar cell panel 20 attached thereon are disposed on the horizontal section 42, and located between the two fixing arms 44. Heat generated by the focused sunlight on the solar cell panel 20 is transferred to the base 12, from which the heat is transferred to the fin set 14 by the heat pipes 16. Finally, the heat is dissipated to the ambient environment through the fins 140.

It is to be understood, however, that even though numerous characteristics and advantages of the present embodiments have been set forth in the foregoing description, together with details of the apparatus and function of the embodiments, the disclosure is illustrative only, and changes may be made in detail, especially in matters of shape, size, and arrangement of parts within the principles of the embodiments to the full extent indicated by the broad general meaning of the terms in which the appended claims are expressed.

1. A solar cell apparatus comprising:
a solar cell panel; and
a heat sink comprising a base, a fin set, and a heat pipe thermally connecting the fin set with the base;
wherein the solar cell panel is attached on a top face of the base of the heat sink.

2. The solar cell apparatus as claimed in claim 1, wherein the base is separated from the fin set.

3. The solar cell apparatus as claimed in claim 2, wherein the fin set comprises a plurality of fins spaced from each other.

4. The solar cell apparatus as claimed in claim 3, wherein the fins are parallel to each other and the base.

5. The solar cell apparatus as claimed in claim 3, wherein the heat pipe comprises an evaporation section and two condensation sections extending from two opposite ends of the evaporation section, respectively and into the fins.

6. The solar cell apparatus as claimed in claim 5, wherein the evaporation section is embedded in the base.

7. The solar cell apparatus as claimed in claim 5, wherein the condensation sections extend perpendicularly through the fins.

8. The solar cell apparatus as claimed in claim 1 further comprises a lens having a light-emergent face facing to the solar cell panel and a light-incident face opposite to the light-emergent face.

9. The solar cell apparatus as claimed in claim 8, wherein a thickness of the lens decreases gradually from a central portion to a periphery of the lens.

10. The solar cell apparatus as claimed in claim 8, wherein a cross section of the lens has a shape of an ellipse.

11. The solar cell apparatus as claimed in claim 8, wherein the lens is made of transparent materials selected from glass, resin, PC (polycarbonate) and PMMA (polymethyl methacrylate).

12. The solar cell apparatus as claimed in claim 8 further comprises a fixing bracket comprising a horizontal section and a pair of fixing arms respectively extending from two opposite ends of the horizontal section, for supporting the lens above the solar cell panel.

13. The solar cell apparatus as claimed in claim 12, wherein a distal end of each of the two fixing arms away from the horizontal section of the fixing bracket is bended to form an engaging portion for abutting against and supporting an edge of the solar cell panel.

14. The solar cell apparatus as claimed in claim 12, wherein the heat sink and the solar cell panel attached thereon are disposed on the horizontal section of the fixing bracket.

15. The solar cell apparatus as claimed in claim 12, wherein the heat sink and the solar cell panel attached thereon are located between the two fixing arms of the fixing bracket.
